(19) United States
(12) Patent Application Publication
(10) Pub. No.: US 2004/0031568 A1
(43) Pub. Date: Feb. 19, 2004

(54) Device for connecting multi-layer boards

(76) Inventor: Joseph Jui-Chin Lin, Tao Yuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/291,412

(22) Filed: Nov. 12, 2002

(30) Foreign Application Priority Data
Aug. 16, 2002 (TW) 091212895

(51) Int. Cl. B32B 31/20; H05K 3/00

(52) U.S. Cl. 156/379.7; 156/288; 156/273.7

(57) ABSTRACT

A device for connecting inner boards of a multi-layer board includes a plurality of conduction pieces such as copper rings on each inner board and a plurality of prepregs are located between the inner boards of a pile of the inner board. A radio heater is enclosed by a pressing member and connected to a radio heater device, the pressing member presses the pile of the inner boards and the conduction pieces is heated to melt the prepregs which release resin to connect the overlapped inner boards within a short period of time.

### FIELD OF THE INVENTION

The present invention relates to a device for connecting multi-player boards by using a radio heater to increase copper rings between the layers so as to melt prepregs and to connect the layers.

### BACKGROUND OF THE INVENTION

The conventional Printed Circuit Board (PCB) is required to be made into a multi-layer board (MLB) so as to contain multiple circuits in the MLB. The process for connecting the multi-layer board includes several steps and each process is required to be precise and environment friendly. It is important to precisely allocate the layers of boards which are required to be thin, light in weight, and having multiple circuits in a limited area. The layers of boards are first piled up and fixed the relative position with each other by snaps, clamps, tapes, rivets, heat-riveting, or special fixing device such as the machine called PIN-LAM. Nevertheless, it takes a lot of time to remove the snaps or the clamps before pressing the layers of board. The layers of boards are easily shifted when pressing so that the conventional way cannot be used on the precise multi-layer boards.

The tapes could be melted when heated and the melted tapes flow out from the gaps between the boards or are burned to be thick particles which increase the width of the gap between the boards. Heat-proof tapes can be used and obtain better results, nevertheless, the heat-proof tapes are suffered high cost.

The rivets made generate metal debris which short the circuit of the boards and the head of the rivets could be too thick to accept for connecting the boards. Heat-riveting has a shortcoming of the slowness of heat conduction if the temperature is low, or the prepregs are burned if the temperature is high. The heat conduction is slower if the prepregs are made of Teflon.

The way of PIN-LAM takes a lot of processing time and the clamping devices or chucks of PIN-LAM are removed from the products manually so that it cannot meet the requirements of mass production.

The present invention intends to provide a device that quickly melts the prepregs between the boards and connects the layers of boards within a short period of time.

### SUMMARY OF THE INVENTION

The present invention relates to a device for connecting inner boards of a multi-layer board by using radio heater device enclosed by a pressing member which presses and heat the pile of the inner boards. Conduction pieces such as copper rings are connected bewteen the inner boards and are heated to melt prepregs which releases resin to connect the inner boards within a short period of time.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows steps of connecting inner boards by the device of the present invention;

FIG. 2 shows holes, conduction pieces, and prepregs on each of the inner boards;

FIG. 3 is a cross sectional view to show the pile of inner boards are pressed and heated by the device of the present invention; and

FIG. 4 shows that a radio heater enclosed by the pressing member is connected to a radio heater device.

### DETAILED DESCRIPTION OF THE PREFERRED EMBODIMENT

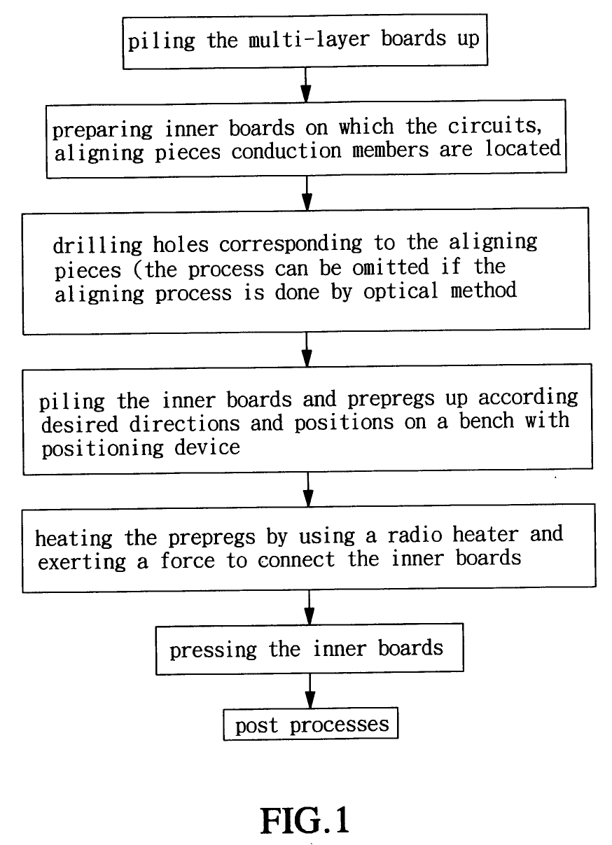

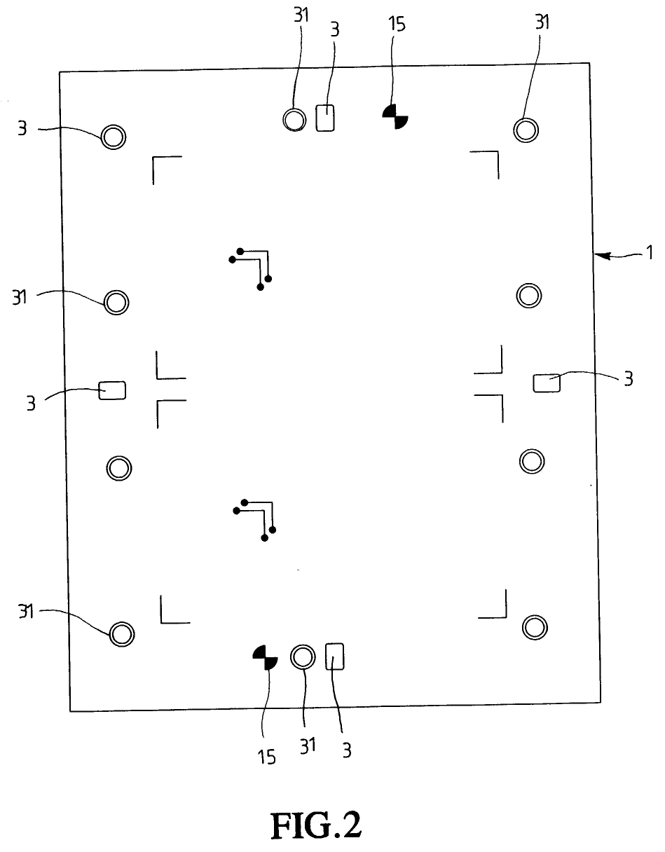

Referring to FIGS. 1 to 3, the device of the present invention is used before the pressing of the multi-layer boards and comprises the following steps:

Step 1: piling the multi-layer boards up;

Step 2: preparing inner boards on which the circuits, aligning pieces and conduction members are located;

Step 3: drilling holes corresponding to the aligning pieces, the process can be omitted if the aligning process is done by optical method;

Step 4: piling the inner boards and prepregs up according desired directions and positions on a bench with positioning device;

Step 5: heating the prepregs by using a radio heater and exerting a force to connect the inner boards;

Step 6: pressing the inner boards; and

Step 7: post processes.

The steps 1, 2, 3, 6 and 7 are known in the field so that they are not described in detail in the description.

The characteristics of the steps 4 and 5 are:

The holes 3 are defined through the inner boards 1 at desired positions and conduction pieces 31 are located on the inner boards 1 corresponding to the holes 3. The conduction pieces 31 can be located proximate to the holes 3 or aligned with the holes 3. The conduction pieces 31 are responsive to heat and can be copper rings.

The prepregs 2 are located between the inner boards 1 which are piled up on the bench in a desired sequence and directions.

A pressing member 4 on the top of the pile of the inner boards 1. A radio heater 5 is received in the pressing member 4 and is connected to a radio heater device 6. The radio heater device 6 may be connected with multiple radio heaters 5. Each radio heater 5 heats a specific fixing position of the pile of the inner boards 1 so as to heat the conduction pieces 31 and melt the prepregs 2. The epoxide resin in the prepregs may enter the rough surface of the inner boards 1 so connect the inner boards 1. By this way, the inner boards 1 can be connected with each other within a short period of time.

The conduction pieces 31 on the inner boards 1 located proximate to the holes 3 may be made as a ring which can also be made simultaneously with the holes 3. The conduction pieces 31 are easily heated and the ring-shaped conduction pieces 31 on the overlapped inner boards 1 are located in alignment with each other.

The way of alignment for the inner boards 1 can be done by aligning holes and pins, aligning edges of the inner boards, optical aligning or mechanical adjustment alignment. The locations of the holes 3 or conduction pieces 31 are set according the thickness, the size and the position where the radio heater 5 is located.

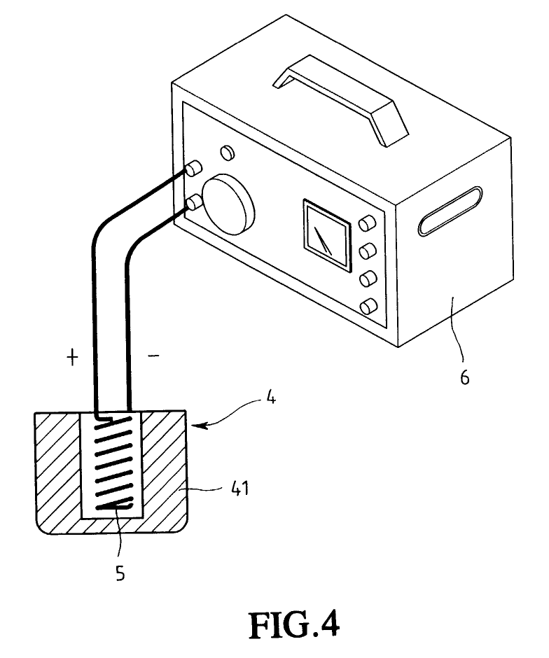

The radio heater 5 is enclosed by a non-conductive material casing so that it will not scrape the surface of the inner boards 1. The surface of the pressing member 4 is made of non-stick material resin such as Teflon. The pressing member 4 and the radio heater 5 can also be made into a one-piece member so as to exert a proper force on the pile of the inner boards 1. The combination of the radio heater 5 and the pressing member 4 is connected to a radio heater device 6 as shown in FIG. 4 so as to press and heat the pile of the inner boards 1.

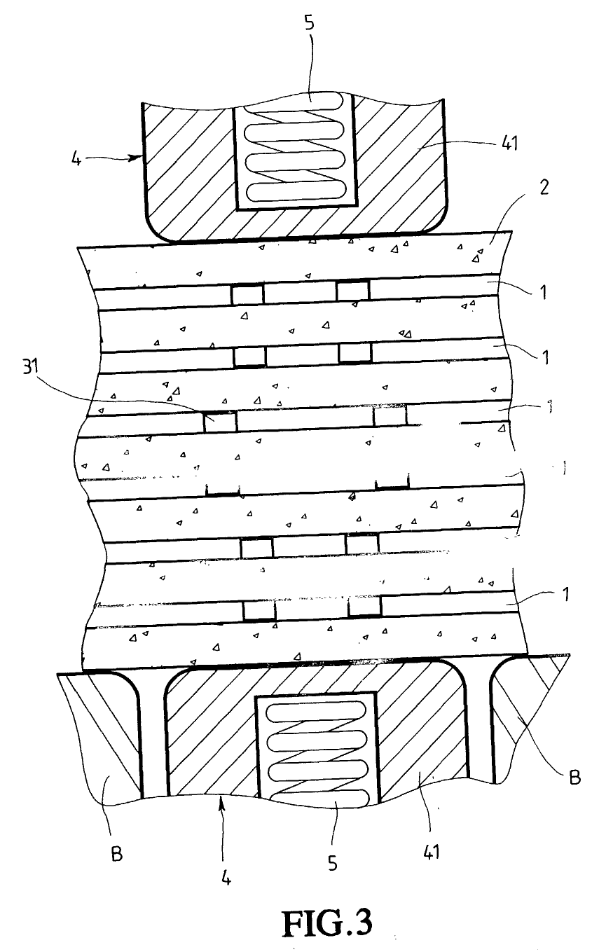

As shown in FIG. 3 which shows the bench “B” for the inner boards 1 to be piled up. A casing 41 in which a radio heater 5 is received can be located above, below or between the benches “B” so as to press and heat the pile of inner boards 1 to melt the prepregs and connect the inner boards 1. The radio heater device 6 can be replaced with any known heating device such as electromagnetic conduction heating device, and the conduction pieces can be electromagnetic conduction pieces.

The way of alignment of the inner boards 1 can be varied as long as the conduction pieces are positioned. The pressing member 4 exerts a force to the pile of inner boards 1 and the force is evenly applied on the inner boards 1 so as to maintain the precision of the relative relationship between the inner boards 1 even when the pressing member 4 is removed.

The conduction pieces 31 can be quickly heated by using the radio heating device 6 and the temperature melts the prepregs which penetrate the surface of the inner boards 1 so as to securely connect the inner boards 1. The heat is generated from the inner layer to the outer layer of the pile of the inner boards 1 which improves the shortcoming of the conventional way wherein the heat generating from outer layer to the inner layer and the temperature could result in deformation of the inner boards 1. If the temperature is too low, the connection force between the inner boards is not enough to firmly connect the boards 1, if the temperature is too high, the perpregs could be burned.

The pressing member 4 is made of non-conductive material and light in weight so that it may apply at a large area on the pile of the inner boards 1 and the stress of connection between the inner boards 1 is small which increases the quality of connection. The conventional way applies a large force to press the inner boards 1 and expects to shorten the time of heating, the large pressure squeeze the resin out from the edges of the boards 1 and area with less amount of rein reduces the connection force. The flow-out resin forms a thick block which affects the gaps between the inner boards 1.

While we have shown and described the embodiment in accordance with the present invention, it should be clear to those skilled in the art that further embodiments may be made without departing from the scope of the present invention.

What is claimed is:

1. A multi-layer board connection device comprising:
a plurality of inner boards being piled up on a bench;
a radio heating device having a pressing member which presses on the pile of the inner boards, each radio heater having at least one radio heater which heats a fixing position of the pile of the inner boards, a pre-determined number of holes defined through the inner boards and conduction pieces located at the holes or proximate to the holes, a prepreg located between the inner boards, the radio heating device hearing the pile of inner boards and pressing member pressing the pile of the inner boards, the conduction pieces being heated to melt the prepregs to release epoxide resin which is engaged with surfaces of the inner boards and connect the inner boards.

2. The device as claimed in claim 1, wherein a plurality of electromagnetic conduction pieces are connected to the inner boards and an electromagnetic conduction heating device heats up the inner boards, the conduction pieces on any two overlapped inner boards being copper rings and located in correspondent with each other.

3. The device as claimed in claim 2, wherein the electromagnetic conduction pieces are ring-shaped and located corresponding to the radio heaters.

4. The device as claimed in claim 1 wherein the radio heater is enclosed by a non-conductive material casing and a surface of the pressing member is made of non-stick material resin.

5. The device as claimed in claim 1 wherein the casing enclosing the radio heater and the radio heater are made as a one-piece member.

6. The device as claimed in claim 1 further comprising at least one radio heater enclosed by the pressing member located on the bench and the at least one radio heater enclosed by the pressing member being connected to the radio heater device.

7. The device as claimed in claim 1, wherein the inner boards are aligned with each other by aligning edges of the inner boards or by checking advance aligning pieces by optical aligning method and mechanical adjustment alignment.

8. The device as claimed in claim 1, wherein the radio heater device may have different electromagnetic conduction devices enclosed by pressing members, the electromagnetic conduction devices located above and/or below the pile of the inner boards.
